(19) United States
(12) Patent Application Publication
(10) Pub. No.: US 2026/0169059 A1
(43) Pub. Date: Jun. 18, 2026

(54) TEMPERATURE ADJUSTMENT APPARATUS AND TESTING APPARATUS FOR INTEGRATED CHIP

(71) Applicant: SHENZHEN LONGSYS ELECTRONICS CO., LTD., SHENZHEN (CN)

(72) Inventors: SHUIQING LI, SHENZHEN (CN); BIN ZHOU, SHENZHEN (CN); GENG LIU, SHENZHEN (CN); PINGZHONG WANG, SHENZHEN (CN); CHENG LIU, SHENZHEN (CN); XIAOQIANG ZHANG, SHENZHEN (CN)

(21) Appl. No.: 19/531,690

(22) Filed: Feb. 6, 2026

Related U.S. Application Data
(63) Continuation of application No. PCT/CN2023/111578, filed on Aug. 7, 2023.

(51) Int. Cl. G01R 31/28

(52) U.S. Cl. CPC G01R 31/2874; G01R 31/2881

(57) ABSTRACT

The present application relates to a temperature adjustment apparatus and a testing apparatus for an integrated chip. The temperature adjustment apparatus is applied to an integrated chip testing scene. The temperature adjustment apparatus includes: a first thermoelectric cooling chip, wherein the first thermoelectric cooling chip has a first end surface configured to attach to one side of to-be-tested integrated chip, and is used for absorbing heat from the integrated chip or transferring heat to the integrated chip; and a heat exchange assembly, attached to a second end face of the first thermoelectric cooling chip and used for performing heat exchange with the first thermoelectric cooling chip.

### CROSS REFERENCE TO RELATED APPLICATIONS

This application is a continuation of International Patent Application No. PCT/CN2023/111578, filed Aug. 7, 2023, which is herein incorporated by reference in its entirety.

### TECHNICAL FIELD

The present disclosure relates to the technical field of integrated chip testing, and in particular, to a temperature adjustment apparatus and a testing apparatus for an integrated chip.

### BACKGROUND

In the current technical field, after manufacturing and processing of integrated chips (such as processing unit chips, or memory chips) are completed, a series of tests need to be performed on the integrated chips to determine whether the integrated chips meet these requirements. Some integrated chips need to work normally in high-temperature and low-temperature environments, so they need to undergo high and low temperature aging tests.

At present, the conventional approach for performing high and low temperature tests on integrated chips is to place the integrated chips into a high and low temperature aging test chamber. The commonly used high and low temperature aging test chambers currently have defects such as poor temperature uniformity, inability to be miniaturized, prone to wear of internal mechanical components, or the like.

### SUMMARY

One technical solution adopted by the present disclosure is to provide a temperature adjustment apparatus. The temperature adjustment apparatus may be applied to an integrated chip testing scenario. The temperature adjustment apparatus may include a first thermoelectric cooling chip and a heat exchange assembly. A first end face of the first thermoelectric cooling chip may be configured to attach to one side of a to-be-tested integrated chip, and may be configured to absorb heat from the to-be-tested integrated chip or transfer heat to the to-be-tested integrated chip. The heat exchange assembly may be attached to a second end face of the first thermoelectric cooling chip, and may be configured to perform heat exchange with the first thermoelectric cooling chip.

Another technical solution adopted by the present disclosure is to provide a testing apparatus for an integrated chip. The testing apparatus may include: a test socket, a test board, and a temperature adjustment apparatus. The test socket may be configured to place the to-be-tested integrated chip. The test board may be coupled to the test socket, and may realize testing of the to-be-tested integrated chip. The temperature adjustment apparatus may be configured to perform temperature adjustment in case of testing the to-be-tested integrated chip. The temperature adjustment apparatus may include a first thermoelectric cooling chip and a heat exchange assembly. A first end face of the first thermoelectric cooling chip may be configured to attach to one side of a to-be-tested integrated chip, and may be configured to absorb heat from the to-be-tested integrated chip or transfer heat to the to-be-tested integrated chip. The heat exchange assembly may be attached to a second end face of the first thermoelectric cooling chip, and may be configured to perform heat exchange with the first thermoelectric cooling chip.

### BRIEF DESCRIPTION OF THE DRAWINGS

To more clearly illustrate technical solutions in the embodiments of the present disclosure, the drawings required for describing the embodiments will be briefly introduced below. Obviously, the drawings described below are only some embodiments of the present disclosure. For those of ordinary skill in the art, other drawings may be obtained based on these drawings without creative efforts.

FIG. 1 is a schematic structural diagram of a temperature adjustment apparatus according to an embodiment of the present disclosure.

FIG. 2 is a schematic structural diagram in a case where a first thermoelectric cooling chip and a first heat-conducting member in FIG. 1 are not in contact.

FIG. 3 is a schematic structural diagram in a case where the first thermoelectric cooling chip and the first heat-conducting member in FIG. 1 are in contact.

FIG. 4 is a schematic structural diagram in a case where the first thermoelectric cooling chip and a second heat-conducting member in FIG. 1 are not in contact.

FIG. 5 is a schematic structural diagram in a case where the first thermoelectric cooling chip and the second heat-conducting member in FIG. 1 are in contact.

FIG. 6 is a schematic structural diagram in a case where a to-be-tested integrated chip and the second heat-conducting member in FIG. 1 are not in contact.

FIG. 7 is a schematic structural diagram in a case where the to-be-tested integrated chip and the second heat-conducting member in FIG. 1 are in contact.

FIG. 8 is a schematic structural diagram of an integrated chip testing apparatus according to an embodiment of the present disclosure.

FIG. 9 is a schematic structural diagram of an integrated chip testing apparatus according to another embodiment of the present disclosure.

FIG. 10 is a schematic structural diagram of an integrated chip testing apparatus according to yet another embodiment of the present disclosure.

FIG. 11 is a schematic structural diagram of an integrated chip testing apparatus according to yet another embodiment of the present disclosure.

FIG. 12 is a schematic structural diagram of an integrated chip testing apparatus according to yet another embodiment of the present disclosure.

FIG. 13 is a schematic flowchart of an integrated chip testing method according to yet another embodiment of the present disclosure.

### DETAILED DESCRIPTION

The technical solutions in the embodiments of the present disclosure would be clearly and completely described below with reference to the accompanying drawings in the embodiments of the present disclosure. Obviously, the described embodiments are only some of the embodiments of the present disclosure, rather than all the embodiments. Based on the embodiments in the present disclosure, all other embodiments obtained by those of ordinary skill in the art without creative efforts shall fall within the protection scope of the present disclosure.

Integrated chips with high operational reliability in harsh cold and high-temperature environments may need to undergo research and development verification, system testing, reliability testing, or production testing in a temperature environment of −45° C.-150° C.

Taking an aging test of integrated chips as an example, functional testing, performance testing, and accelerated aging testing may need to be performed on the integrated chips in high-temperature (such as 110° C., 125° C., or 150° C.) , room-temperature (such as 20° C., 25° C., or 30° C.) , and low-temperature (such as −25° C., −40°C., or −50° C.) environments to screen out defective products that do not meet the requirements.

Currently, common apparatuses for performing high and low temperature tests on integrated chips may mainly include: high and low temperature chambers using compressor for refrigeration and electric heating for heating, and high and low temperature chambers using liquid nitrogen refrigeration and electric heating strips for heating.

Regarding the high and low temperature chamber using compressor for refrigeration and electric heating for heating, the high and low temperature chamber may achieve an ambient temperature of −70° C.-150° C. inside the chamber, and the ambient temperature inside the high and low temperature chamber may be dynamically adjusted.

Regarding the high and low temperature chamber using liquid nitrogen for refrigeration and electric heating strips for heating, the high and low temperature chamber may achieve an ambient temperature of −150° C.-150° C. inside the chamber, and the ambient temperature inside the high and low temperature chamber may be dynamically adjusted.

The inventors of the present disclosure have found that, the currently common high and low temperature chambers have the defect of low temperature rise and fall efficiency. These chambers may take ten minutes to half an hour to adjust the temperature inside the chamber to a specified temperature, and after reaching a specified temperature, these chambers may be necessary to wait for a long time to achieve temperature uniformity in each area inside the chamber. Common high and low temperature chambers use compressors or liquid nitrogen for refrigeration and electric hot air for heating. This may result in wear of mechanical components and loss of refrigerants. Further, when the to-be-tested chip undergoes high and low temperature tests in the high and low temperature chamber, since a test board is also placed in the high and low temperature chamber, some current test boards may not be resistant to high and low temperatures and may not be able to test the to-be-tested chip. Even if the components of the test board are made of high and low temperature resistant materials, the stability of the test board in long-term high and low temperature environments may still not be guaranteed. After several high and low temperature tests on the to-be-tested integrated chip, the test board may need to be replaced to ensure the stability of the test of the to-be-tested integrated chip, thereby significantly increasing test cost.

The present disclosure mainly designs a set of temperature adjustment apparatus for independently adjusting temperature of the to-be-tested integrated chip. Different from traditional methods, on the one hand, when the to-be-tested integrated chip undergoes high and low temperature tests, the temperature adjustment apparatus designed by the present disclosure may not require additional installation of other mechanical components to assist in refrigeration or heating, thereby further enhancing the operational reliability of the temperature adjustment apparatus.

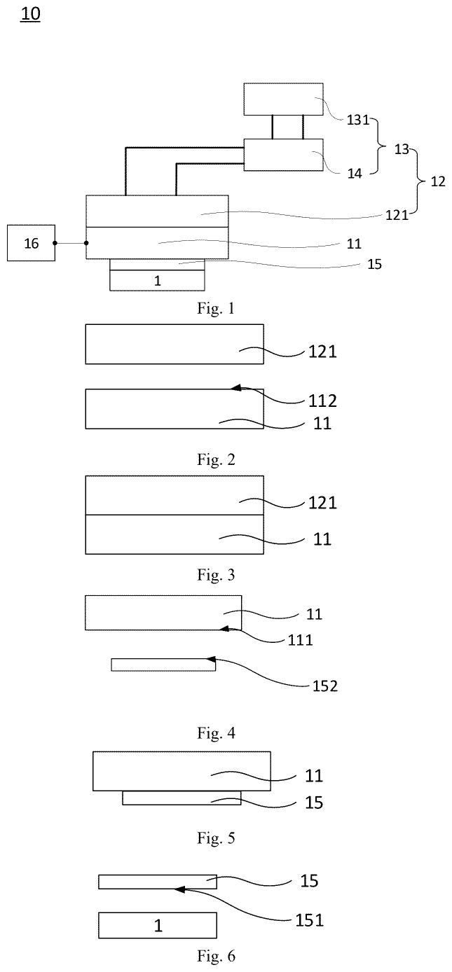

Please refer to FIG. 1 for details. FIG. 1 is a schematic structural diagram of a temperature adjustment apparatus according to an embodiment of the present disclosure.

As illustrated in FIG. 1, the temperature adjustment apparatus 10 of the embodiment of the present disclosure may include a first thermoelectric cooling chip 11 and a heat exchange assembly 12.

A first end face 111 of the first thermoelectric cooling chip 11 may be configured to attach to one end face of a to-be-tested integrated chip 1, and may be configured to absorb heat from the to-be-tested integrated chip 1 or transfer heat to the to-be-tested integrated chip. The first thermoelectric cooling chip 11 may be configured to heat or cool the to-be-tested integrated chip 1.

In some embodiments, the to-be-tested integrated chip 1 may be a processor device. In some application scenarios, the processor device may be a central processing unit (CPU). In some application scenarios, the processor device may be a graphic processing unit (GPU). In some application scenarios, the processor device may be an integrated circuit chip with signal processing capability. In some application scenarios, the processor device may also be a general-purpose processor, a digital signal processor (DSP), an application-specific integrated circuit (ASIC), a field-programmable gate array (FPGA), or other programmable logic devices, discrete gate or transistor logic devices, or discrete hardware components. The general-purpose processor may be a microprocessor, or the processor device may be any conventional processor, or the like.

In some embodiments, the to-be-tested integrated chip 1 may be a storage medium, such as a flash memory chip. In some application scenarios, the storage medium may be a U disk, a mobile hard disk, a read-only memory (ROM), a random-access memory (RAM), a flash memory card, or a magnetic disk.

In some embodiments, the tests performed on the to-be-tested integrated chip may include functional testing, performance testing, and/or reliability testing of the to-be-tested chip at different temperatures. Further, the reliability testing may include (high-temperature/low-temperature) temperature cycle testing, high-temperature operating life (HTOL) testing, temperature and humidity (TH/THB) testing, and/or high-temperature storage (HTSL) testing, or the like.

In some application scenarios, the temperature adjustment apparatus 10 may also be used in an operating scenario of the to-be-tested integrated chip 1. For example, if the normal operating temperature of a certain to-be-tested integrated chip 1 is lower than minus 100 degrees Celsius, the temperature adjustment apparatus 10 may maintain the to-be-tested integrated chip 1 within its normal operating temperature range.

In some embodiments, the first thermoelectric cooling chip 11 may adopt the Peltier effect to perform any one of cooling, heating, and temperature maintaining operations on the to-be-tested integrated chip 1.

The principle of the Peltier effect is that a thermocouple pair is formed by connecting a plate of N-type semiconductor (electron-type semiconductor) material and a plate of P-type semiconductor (hole-type semiconductor) material. When electric current passes through the thermocouple pair, heat transfer occurs between outer end faces of the two semiconductors, and heat is transferred from one end face to another, thereby generating a temperature difference to form a cold end face and a hot end face. The heat of the cold end face is transferred to the hot end face. However, due to the inherent resistance of the semiconductor material itself, heat may be generated when the electric current flows through the semiconductor material, thereby affecting heat transfer. Further, heat between the two plates may also be reversely transferred through air and/or the semiconductor material itself. When the cold end face and the hot end face reach a certain temperature difference, the heat of forward heat transfer is equal to the heat of reverse heat transfer, and the temperatures of the cold end face and the hot end face may not change any more.

Taking the cooling of the to-be-tested integrated chip 1 by the first thermoelectric cooling chip 11 as an example, at this time, the temperature of the first end face 111 in contact with one side of the to-be-tested integrated chip 1 is lower than the temperature of a second end face 112. In other words, the first end face 111 may form a cold face and the second end face 112 may form a hot face. To reduce the temperature of the first end face 111, it may be necessary to further reduce the temperature of the second end face 112. That is, to accelerate the speed at which the first thermoelectric cooling chip 11 absorbs heat from the to-be-tested integrated chip 1, it may be necessary to timely conduct the heat of the second end face 112 to another component with lower temperature than that of the second end face 112.

Taking the heating of the to-be-tested integrated chip 1 by the first thermoelectric cooling chip 11 as an example, at this time, the temperature of the first end face 111 in contact with one side of the to-be-tested integrated chip 1 is higher than the temperature of the second end face 112. In other words, the first end face 111 may form the hot face and the second end face 112 may form the cold face. To increase the temperature of the first end face 111, it may be necessary to further increase the temperature of the second end face 112. In other words, to accelerate the speed at which the first thermoelectric cooling chip 11 transfers heat to the to-be-tested integrated chip, it may be necessary to timely use another component with higher temperature than the second end face 112 to transfer heat to the second end face 112.

The heat exchange assembly 12 may be attached to the second end face 112 of the first thermoelectric cooling chip 11. The heat exchange assembly 12 may be configured to perform heat exchange with the first thermoelectric cooling chip 11.

In some application scenarios, the first thermoelectric cooling chip 11 may be configured to cool the to-be-tested integrated chip 1. In a case where the first thermoelectric cooling chip 11 dissipates the heat absorbed from the to-be-tested integrated chip 1, the heat of the first end face 111 may increase, and the temperature of the first end face 111 may rise. Further, the temperature of the second end face 112 may also rise accordingly. At this time, the heat exchange assembly 12 attached to the second end face 112 may absorb the heat of the second end face 112, thereby reducing the temperature of the second end face 112, accelerating the heat conduction in the first thermoelectric cooling chip 11, and enabling the to-be-tested integrated chip 1 to cool down quickly.

In some application scenarios, the first thermoelectric cooling chip 11 may be configured to heat the to-be-tested integrated chip 1. When the first thermoelectric cooling chip 11 transfers heat to the to-be-tested integrated chip 1. That is, the heat of the first end face 111 decreases, and the temperature of the first end face 111 may decrease. Further, the temperature of the second end face 112 may also decrease accordingly. At this time, the heat exchange assembly 12 attached to the second end face 112 may transfer heat to the second end face 112, thereby increasing the temperature of the second end face 112, accelerating the heat conduction of the first thermoelectric cooling chip 11, and enabling the to-be-tested integrated chip 1 to heat up quickly.

In some application scenarios, the first thermoelectric cooling chip 11 may also be configured to maintain the temperature of the to-be-tested integrated chip 1, and the heat exchange assembly 12 may be configured to maintain the heat of the first thermoelectric cooling chip 11.

Optionally, the heat exchange assembly 12 may be an air-cooling assembly. For example, the air-cooling assembly may be an air conditioner or an air-cooling radiator, which is not limited herein.

In some embodiments, the heat exchange assembly 12 may be a liquid-cooling assembly. For example, the liquid-cooling assembly may be a water-cooling radiator or an oil-cooling radiator, which is not limited herein.

In some embodiments, the temperature adjustment apparatus 10 may further include a temperature sensor (not illustrated in the drawings). In some embodiments, the temperature sensor may be attached between the first end face 111 of the first thermoelectric cooling chip 11 and the surface of the to-be-tested integrated chip 1. In some embodiments, the temperature sensor may be attached to the surface of the to-be-tested integrated chip 1.

For example, the temperature sensor may be configured to obtain current temperature value of the to-be-tested integrated chip 1. Further, control parameters of the first thermoelectric cooling chip 11 may be determined according to the difference between the current temperature value and a preset temperature value, thereby controlling the first thermoelectric cooling chip 11 to perform heating or cooling operations.

In some embodiments, the heat exchange assembly 12 may include a first heat-conducting member 121 and a liquid cooling assembly 13. The first heat-conducting member 121 may be attached to the second end face 112, and may be configured to conduct heat from the liquid cooling assembly 13 to the second end face 112, that is, conduct heat from the liquid cooling assembly 13 to the first thermoelectric cooling chip 11. Alternatively, the first heat-conducting member 121 may be configured to conduct heat from the second end face 112 to the liquid cooling assembly 13, that is, conduct heat from the first thermoelectric cooling chip 11 to the liquid cooling assembly 13.

In some application scenarios, the first heat-conducting member 121 may be a metal with good thermal conductivity (such as copper, aluminum, platinum), a metal oxide or alloy, or a heat-conducting material represented by graphene, phase-change thermally conductive insulating material, thermal pad, thermal filler, thermal pad, or the like, which is not limited herein.

Further, a part of liquid cooling circuit of the liquid cooling assembly 13 may be disposed in the first heat-conducting member 121, and coolant may be configured to circulate in the liquid cooling circuit to perform heat exchange with the first heat-conducting member 121.

In some embodiments, the heat exchange between the liquid cooling assembly 13 and the first heat-conducting member 121 may include any one of: absorbing heat from the first heat-conducting member 121, conducting heat to the first heat-conducting member 121, and maintaining the heat in the first heat-conducting member 121.

In some application scenarios, the first thermoelectric cooling chip 11 may be configured to absorb heat from the to-be-tested integrated chip 1. Part or all of the heat absorbed by the first thermoelectric cooling chip 11 may be conducted to the first heat-conducting member 121, so that the heat in the first heat-conducting member 121 increases, that is, the temperature of the first heat-conducting member 121 rises, and the speed at which the first heat-conducting member 121 absorbs heat from the first thermoelectric cooling chip 11 may gradually decrease. At this time, the temperature of the coolant in the liquid cooling assembly 13 is lower than the temperature of the first heat-conducting member 121, and the coolant in the liquid cooling assembly 13 may perform heat exchange with the first heat-conducting member 121 to absorb the heat of the first heat-conducting member 121, and the temperature of the first heat-conducting member 121 may decrease. Further, the speed at which the first heat-conducting member 121 with a reduced temperature absorbs heat from the first thermoelectric cooling chip 11 may gradually increase.

In some application scenarios, the first thermoelectric cooling chip 11 may be configured to transfer heat to the to-be-tested integrated chip 1. The first heat-conducting member 121 may transfer heat to the first thermoelectric cooling chip 11, resulting in a decrease in the heat of the first heat-conducting member 121, in other words, the temperature of the first heat-conducting member 121 may decrease, and the speed at which the first heat-conducting member 121 transfers heat to the first thermoelectric cooling chip 11 may gradually decrease. At this time, if the temperature of the coolant in the liquid cooling assembly 13 is higher than that of the first heat-conducting member 121, the coolant in the liquid cooling assembly 13 may transfer heat to the first heat-conducting member 121, causing the temperature of the first heat-conducting member 121 to rise. Further, the speed at which the first heat-conducting member 121 with an increased temperature transfers heat to the first thermoelectric cooling chip 11 may gradually increase.

In some application scenarios, the first thermoelectric cooling chip 11 may be configured to maintain the heat of the to-be-tested integrated chip 1. The first heat-conducting member 121 may neither transfer heat to the first thermoelectric cooling chip 11 nor absorb heat from the first thermoelectric cooling chip 11. Similarly, the coolant in the liquid cooling assembly 13 may neither transfer heat to the first heat-conducting member 121 nor absorb heat from the first heat-conducting member 121.

In some embodiments, the coolant in the liquid cooling assembly 13 may be a liquid with strong heat absorption capacity, such as pure water, ethylene glycol aqueous solution, ethylene glycol water-based antifreeze, glycerol aqueous solution, or glycerol water-based antifreeze, which is not limited herein.

After long-term research, the inventors of the present disclosure have found that current conventional types of heat exchange assemblies include air-cooling assemblies and conventional liquid-cooling assemblies, and the radiator of a conventional liquid-cooling assembly may need to be equipped with a cooling fan. Taking the refrigeration scenario as an example, air-cooling assemblies have the defect of poor cooling efficiency and the limitation of being unable to further reduce the temperature of the second end face (hot face) of the thermoelectric cooling chip. Conventional air-cooling assemblies may only maintain the temperature of the first end face (cold face) of the thermoelectric cooling chip at 0° C. or above. Compared with air-cooling assemblies, conventional liquid-cooling assemblies have higher heat dissipation efficiency, but conventional liquid-cooling components may only maintain the temperature of the first end face (cold face) of the thermoelectric cooling chip at −20° C. or above. Meanwhile, the aforementioned air-cooling assemblies and conventional liquid-cooling assemblies have the limitation of being unable to heat the second end face (cold face) of the thermoelectric cooling chip in the heating scenario.

To address shortcomings of the above conventional technical means, the inventors of the present disclosure have additionally arranged a second thermoelectric cooling chip 131 on the liquid cooling assembly 13. The second thermoelectric cooling chip 131 may be in contact with another part of the liquid cooling circuit of the liquid cooling assembly 13, and may be configured to perform heat exchange with the liquid cooling circuit.

In some embodiments, the heat exchange between the second thermoelectric cooling chip 131 and the liquid cooling circuit may include any one of: absorbing heat from the coolant in the liquid cooling circuit, releasing heat to the coolant in the liquid cooling circuit, and maintaining the heat of the coolant in the liquid cooling circuit.

In some application scenarios, the first end face 111 may be configured to absorb heat from the to-be-tested integrated chip 1, and the second thermoelectric cooling chip 131 may absorb heat from the second end face 112 through the liquid cooling assembly 13, thereby reducing the temperature of the second end face 112. At this time, the heat of the coolant in the liquid cooling assembly 13 may increase, and the second thermoelectric cooling chip 131 may be configured to absorb heat from the coolant.

In some application scenarios, the first end face 111 may be configured to dissipate heat to the to-be-tested integrated chip 1, and the second thermoelectric cooling chip 131 may release heat to the second end face 112 through the liquid cooling assembly 13, thereby increasing the temperature of the second end face 112. At this time, the heat of the coolant in the liquid cooling assembly 13 may decrease, and the second thermoelectric cooling chip 131 may be configured to release heat to the coolant.

In some application scenarios, if the test requirement for the to-be-tested integrated chip 1 is to neither absorb heat from nor transfer heat to the to-be-tested integrated chip 1, any one or more of the first thermoelectric cooling chip 11, the second thermoelectric cooling chip 131, and the liquid cooling assembly 13 may not work.

By arranging the second thermoelectric cooling chip in contact with another part of the cooling circuit of the liquid cooling assembly, according to the test requirements of the to-be-tested integrated chip, heat from the coolant may be absorbed when the heat of the coolant in the cooling circuit increases. Alternatively, heat may be released to the coolant when the heat of the coolant in the cooling circuit decreases. Further, switching between absorbing heat from the coolant and releasing heat to the coolant may be achieved by reversing the voltage applied across the second thermoelectric cooling chip.

In some embodiments, the outer surface of another part of the cooling circuit in the liquid cooling assembly 13 may be partially or fully sheathed with a heat-conducting member (not illustrated in the drawings) with strong heat transfer capability, and the second thermoelectric cooling chip 131 may be attached to the outer surface of the heat-conducting member. In some embodiments, the heat-conducting member may be a metal with good thermal conductivity (such as copper, aluminum, platinum), a metal oxide or alloy, or a heat-conducting material represented by graphene, phase-change thermally conductive insulating material, thermal pad, thermal filler, or thermal pad, or the like, which is not limited herein.

In some embodiments, the second thermoelectric cooling chip 131 may be attached to the outer surface of another part of the cooling circuit in the liquid cooling assembly 13.

In some embodiments, the liquid cooling assembly 13 may further be provided with a radiator 14. The radiator 14 may be configured to further dissipate the heat absorbed by the coolant in a case where the coolant absorbs heat from the first heat-conducting member 121.

For example, the radiator 14 may be an air-cooling radiator.

In some application scenarios, the first end face 111 may be configured to absorb heat from the to-be-tested integrated chip 1, and the liquid cooling assembly 13 may absorb heat from the second end face 112 through the first heat-conducting member 121, thereby reducing the temperature of the second end face 112. At this time, the heat of the coolant in the liquid cooling assembly 13 may increase. The coolant that has absorbed heat may first pass through the radiator 14, and the radiator 14 may partially dissipate the heat absorbed by the coolant to the surrounding environment. In other words, the coolant may undergo partial cooling. Further, the partially cooled coolant may undergo secondary cooling through the second thermoelectric cooling chip 131, thereby lowering the temperature of the coolant and further enhancing the heat absorption capacity of the coolant.

In some application scenarios, in a case where the coolant releases heat to the first heat-conducting member 121, the radiator 14 may not work.

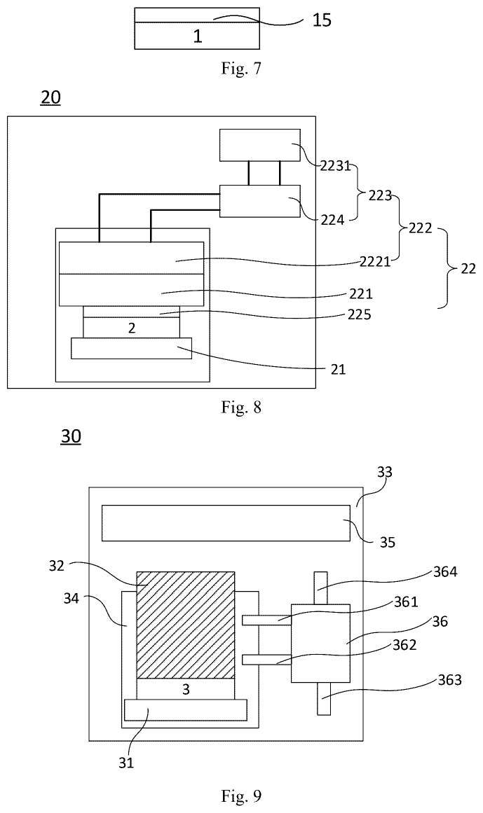

In some embodiments, to enhancing the heat transfer efficiency between the to-be-tested integrated chip 1 and the first thermoelectric cooling chip 11, the temperature adjustment apparatus 10 may further include a second heat-conducting member 15 as illustrated in FIG. 4 to FIG. 7. A first end face 151 of the second heat-conducting member 15 may be configured to attach to one side of the to-be-tested integrated chip 1, and the second heat-conducting member 15 may be configured to perform heat exchange with the to-be-tested integrated chip 1. In some embodiments, the heat exchange between the second heat-conducting member 15 and the to-be-tested integrated chip 1 may include any one of: absorbing heat from the to-be-tested integrated chip 1, transferring heat to the to-be-tested integrated chip 1, and maintaining the heat of the to-be-tested integrated chip 1.

Further, a second end face 152 of the second heat-conducting member 15 may be attached to the second end face 112 of the first thermoelectric cooling chip 11.

In some embodiments, the second heat-conducting member 15 may be a metal with good thermal conductivity (such as copper, aluminum, platinum), a metal oxide or alloy, or a heat-conducting material represented by graphene, phase-change thermally conductive insulating material, thermal pad, thermal filler, or thermal pad, or the like, which is not limited herein.

In some embodiments, hardness of the second end face 152 of the second heat-conducting member 15 may be less than or equal to the hardness of a side surface of the to-be-tested integrated chip 1, so as to prevent the second heat-conducting member 15 from scratching the surface of the to-be-tested integrated chip 1.

By arranging the second heat-conducting member between one side of the to-be-tested integrated chip and the second end face of the first thermoelectric cooling chip, the heat transfer efficiency between the to-be-tested integrated chip and the first thermoelectric cooling chip may be further enhanced.

In some embodiments, a heat-conducting material may be coated between the second end face 152 of the second heat-conducting member 15 and the first end face 111 of the first thermoelectric cooling chip 11.

In some embodiments, the heat-conducting material may be coated between the first end face 151 of the second heat-conducting member 15 and one side of the to-be-tested integrated chip 1.

In some embodiments, the heat-conducting material may be a metal with good thermal conductivity (such as copper, aluminum, platinum), a metal oxide or alloy, or a heat-conducting material such as graphene, phase-change thermally conductive insulating material, thermal pad, thermal filler, or thermal pad, or the like, which is not limited herein.

In some embodiments, the first thermoelectric cooling chip 11 may be a single-stage Peltier element.

In some embodiments, in a case of dissipating the heat absorbed from the to-be-tested integrated chip 1, the first end face 111 of the first thermoelectric cooling chip 11 may be the cold face, and the second end face 112 may be the hot face.

In some embodiments, in a case of transferring heat to the to-be-tested integrated chip 1 through the first thermoelectric cooling chip 11, the first end face 111 of the first thermoelectric cooling chip 11 may be the hot face, and the second end face 112 may be the cold face.

After a period of research, the inventors of the present disclosure have found that in the related art, thermoelectric cooling device adopts multi-stage Peltier cooling chips to further reduce the temperature of the cold face in contact with the to-be-tested integrated chip. For example, a three-stage Peltier cooling chip may generate a low temperature of −107° C. However, the above-mentioned conventional technical means have the defect of low heat dissipation efficiency. Since the heat dissipation efficiency of the hot face of each stage of Peltier cooling chip is limited by the heat transfer power of the cascaded Peltier cooling chip on the hot face, it is impossible to maintain a sufficiently large cooling capacity while reducing the temperature. Taking the three-stage Peltier cooling chip as an example, while generating a low temperature of −107° C., the cooling power is only 17 W. Considering that integrated chips may undergo stress testing in low-temperature environments (such as the range from −50° C. to 0° C.) in integrated chip testing scenarios, the above-mentioned multi-stage Peltier cooling chip scheme may not continuously maintain the to-be-tested integrated chip at a low temperature in scenarios where the integrated chip with high thermal design power consumption (such as greater than 50 W or greater than 100 W) undergoes stress testing.

In the multi-stage Peltier cooling chip scheme, a first face of the first-stage Peltier cooling chip may be attached to one side of the chip under test, the second-stage Peltier cooling chip may be attached to a second face of the first-stage Peltier cooling chip, and so on. Moreover, as the number of stages increases, the area of the Peltier cooling chip becomes smaller. If the multi-stage Peltier cooling chips need to transfer heat to the to-be-tested integrated chip, the heat absorbed by the second face of the first-stage Peltier cooling chip may be greater than the heat generated by the first face of the second-stage Peltier cooling chip, the area of the second-stage Peltier cooling chip is less than that of the first-stage Peltier cooling chip. Further, in the multi-stage Peltier cooling chip scheme, the number of pairs of bismuth telluride particles on the cold face of the Peltier cooling chip may be different from that on the hot face of the Peltier cooling chip, it is not possible to achieve the function of reversing the voltage applied to the Peltier cooling plate for heating. Therefore, the multi-stage Peltier cooling chip scheme cannot achieve both cooling and heating functions without adding another heating apparatus.

By applying the single-stage Peltier element scheme, on the one hand, it may not only dissipate the heat absorbed from the to-be-tested integrated chip but also transfer heat to the to-be-tested integrated chip. On another hand, cooling power of the single-stage Peltier element may reach 200 W, which may also achieve rapid cooling of the to-be-tested integrated chip with heat generation exceeding 20 W.

In some embodiments, the temperature adjustment apparatus 10 may further be provided with a temperature adjustment unit 16. The temperature adjustment unit 16 may be configured to perform voltage inversion on the first end face 111 and the second end face 112 of the first thermoelectric cooling chip 11 to realize switching between the cold face and the hot face.

In some embodiments, the temperature adjustment unit 16 may also be configured to perform voltage inversion on the two end faces of the second thermoelectric cooling chip 131 to realize switching between the cold face and the hot face.

In some application scenarios, the temperature adjustment unit 16 may also be part of a microcontroller unit (MCU) (not illustrated in the drawings).

The above scheme, on the one hand, uses the thermoelectric cooling chip attached to one side of the to-be-tested integrated chip to independently realize the cooling or heating of the to-be-tested integrated chip. The above scheme further uses the heat exchange assembly attached to the first thermoelectric cooling chip to accelerate the speed at which the first thermoelectric cooling chip absorbs heat from the to-be-tested integrated chip or transfers heat to the to-be-tested integrated chip, so that the to-be-tested integrated chip may cool down or heat up quickly. The testing efficiency of the to-be-tested integrated chip may be enhanced.

On the other hand, by arranging a second thermoelectric cooling chip in contact with the liquid cooling circuits in the heat exchange assembly: the second thermoelectric cooling chip may absorb heat from the coolant in the liquid cooling circuits, thereby further reducing the temperature of the second end face of the first thermoelectric cooling chip and enabling its first end face to reach a lower temperature; or, the second thermoelectric cooling chip may transfer heat to the coolant, thereby further increasing the temperature of the second end face of the first thermoelectric cooling chip and enabling its first end face to reach a higher temperature. In this way, the to-be-tested integrated chip may heat up or cool down faster, and the surface temperature of the to-be-tested integrated chip may easily reach below −40° C. or above 100° C.

Please refer to FIG. 8. FIG. 8 is a schematic structural diagram of an integrated chip testing apparatus according to an embodiment of the present disclosure.

As illustrated in FIG. 8, the integrated chip testing apparatus 20 may include a test socket 21, a temperature adjustment apparatus 22, a first space, and a second space.

The test socket 21 may be configured to place the to-be-tested integrated chip 2. In some embodiments, the test socket 21 may also be referred to as a chip test base.

Further, the integrated chip testing apparatus may also include a test board (not illustrated in the drawings). The test board may be coupled to the test socket 21 to realize the testing of the to-be-tested integrated chip 2.

In some embodiments, the test socket 21 may be part of the test board. The test socket 21 may further be configured to test the to-be-tested integrated chip 2. In some embodiments, the test socket 21 may not be directly mounted on the test board. Instead, the test board may be coupled to the test socket 21 through wires/cables. The separate arrangement of the test socket 21 and the test board may allow the test board to avoid being subjected to high or low temperature tests simultaneously with the to-be-tested integrated chip 2.

The to-be-tested integrated chip 2 may correspond to the to-be-tested integrated chip 1 mentioned above, the details of the to-be-tested integrated chip 2 are thus not repeated herein.

The temperature adjustment apparatus 22 may be configured to adjust the temperature while performing tests on the to-be-tested integrated chip 2.

The temperature adjustment apparatus 22 may further include a first thermoelectric cooling chip 221, a heat exchange assembly 222, a first heat-conducting member 2221, a liquid cooling assembly 223, a second thermoelectric cooling chip 2231, a radiator 224, and a second heat-conducting member 225.

The first thermoelectric cooling chip 221 may correspond to the first thermoelectric cooling chip 11 mentioned above. The heat exchange assembly 222 may correspond to the heat exchange assembly 12 mentioned above. The first heat-conducting member 2221 may correspond to the first heat-conducting member 121 mentioned above. The liquid cooling assembly 223 may correspond to the liquid cooling assembly 13 mentioned above. The second thermoelectric cooling chip 2231 may correspond to the second thermoelectric cooling chip 131 mentioned above. The radiator 224 may correspond to the radiator 14 mentioned above. The second heat-conducting member 225 may correspond to the second heat-conducting member 15 mentioned above. The details of these elements are thus not repeated herein.

Further, the second space may be accommodated or defined within the first space. In some embodiments, the second space may be configured to house the to-be-tested integrated chip 2, the test socket 21, the first thermoelectric cooling chip 221, and the second heat-conducting member 225, so that the to-be-tested integrated chip 2 may meet the testing requirements at the target temperature.

In some embodiments, the test board may be disposed in the second space to shorten the distance between the test board and the test socket 21, thereby meeting high-speed transmission requirements between the to-be-tested integrated chip 2 and the test board.

In some embodiments, the test board may be disposed in the first space.

In some embodiments, the first space may be a test cabinet. In some embodiments, the first space may be a test chamber.

In some embodiments, the second space may be a test box.

The volume of the first space may be greater than that of the second space.

In some application scenarios, the target temperature may be any one or more of: the temperature ranges of −60° C.-−20° C., −20° C.-30° C., 30° C.-105° C., and 105° C.-160° C., which is not limited herein. For example, the target temperature may be −50° C., −40° C., −20° C., 0° C., 10° C., 20° C., 25° C., 30° C., 60° C., 80° C., 90° C., 100° C., 105° C., 110° C., 120° C., or 150° C.

In the present embodiment, the first space may be configured to accommodate the liquid cooling assembly 223.

In some application scenarios, considering that the heat exchange assembly 222 may occupy a relatively large space, some components of the heat exchange assembly 222 may be partially accommodated in the second space, and other components of the heat exchange assembly 222 may be accommodated in the first space. For example, the first heat-conducting member 2221 may be accommodated in the second space. Other components of the heat exchange assembly 222, including the second thermoelectric cooling chip 2231 and the radiator 224, may be accommodated in the first space.

In some application scenarios, in a case where the volume of the first space is relatively small and cannot fully accommodate the heat exchange assembly 222, the second thermoelectric cooling chip 2231 and the radiator 224 of the heat exchange assembly 222 may be disposed outside the first space.

In some application scenarios, in a case where the heat exchange assembly 222 installed in the first space may have insufficient heat dissipation capacity, the second thermoelectric cooling chip 2231 and the radiator 224 of the heat exchange assembly 222 may be disposed outside the first space to further enhance the heat dissipation capacity of the heat exchange assembly 222.

In some application scenarios, a dehumidification apparatus (not illustrated in the drawings) and a humidification apparatus (not illustrated in the drawings) may be disposed in the second space. The humidification apparatus may be configured to adjust the humidity during the high-temperature and high-humidity test of the to-be-tested integrated chip 2. The dehumidification apparatus may be configured to adjust the humidity during other tests of the to-be-tested integrated chip 2.

For the above scheme, on the one hand, the thermoelectric cooling chip attached to one side of the to-be-tested integrated chip may be configured to independently realize the cooling or heating of the to-be-tested integrated chip. Further, the heat exchange assembly attached to the first thermoelectric cooling chip may be configured to accelerate the speed at which the first thermoelectric cooling chip absorbs heat from the to-be-tested integrated chip or transfers heat to the to-be-tested integrated chip, so that the to-be-tested integrated chip may cool down or heat up quickly, and the testing efficiency of the to-be-tested integrated chip may be enhanced.

On the other hand, by arranging a second thermoelectric cooling chip in contact with the liquid cooling circuits in the heat exchange assembly: the second thermoelectric cooling chip may absorb heat from the coolant in the liquid cooling circuits, thereby further reducing the temperature of the second end face of the first thermoelectric cooling chip and enabling its first end face to reach a lower temperature; or, the second thermoelectric cooling chip may transfer heat to the coolant, thereby further increasing the temperature of the second end face of the first thermoelectric cooling chip and enabling its first end face to reach a higher temperature. In this way, the to-be-tested integrated chip may heat up or cool down faster, and the surface temperature of the to-be-tested integrated chip may easily reach below −40° C. or above 100° C.

Please refer to FIG. 9. FIG. 9 is a schematic structural diagram of an integrated chip testing apparatus according to another embodiment of the present disclosure.

As illustrated in FIG. 9, the integrated chip testing apparatus 30 in the present embodiment may specifically include: a test socket 31, a temperature adjustment apparatus 32, a first space 33, a second space 34, a first dehumidification apparatus 35, and a second dehumidification apparatus 36.

The test socket 31 may correspond to the test socket 21 mentioned above. The temperature adjustment apparatus 32 may correspond to the temperature adjustment apparatus 22 mentioned above. Details are not repeated herein.

The first space 33 may be configured to accommodate the second space 34.

In some embodiments, the second space 34 may be configured to house the test socket 31 and the to-be-tested integrated chip 3. Further, the second space 34 may partially accommodate the temperature adjustment apparatus 32. More particularly, the first space 33 may be configured to accommodate the structures of the temperature adjustment apparatus 32 that cannot be accommodated in the second space 34.

A first dehumidification apparatus 35 may be disposed in the first space 33. The first dehumidification apparatus 35 may be configured to reduce the humidity in the first space 33 according to a first dehumidification degree, or reduce the humidity in both the first space 33 and the second space 34 according to the first dehumidification degree.

In some embodiments, the first dehumidification apparatus 35 may be any of an air conditioner or a dehumidifier, or a combination thereof, which is not limited herein.

In some embodiments, a second dehumidification apparatus 36 may be disposed in the first space 33. The second dehumidification apparatus 36 may interact or communicate with the second space 34. More particularly, the second dehumidification apparatus 36 may conduct air communication with the second space 34 through a first air intake channel 361 and a first air exhaust channel 362. The second dehumidification apparatus 36 may be configured to reduce the humidity in the second space 34 to a target humidity according to a second dehumidification degree. The humidity of the first air in the first air intake channel 361 may be greater than that of the second air in the first air exhaust channel 362.

The first dehumidification degree may be less than the second dehumidification degree.

In some embodiments, the first dehumidification degree may characterize the ability of the first dehumidification apparatus 35 to adjust the humidity of the first space 33 and/or the second space 34, for example, reducing the humidity of the first space 33 and/or the second space 34 to 45%, 40%, 39%, 38%, 37%, 36%, 35%, 34%, 33%, 32%, 31%, 30%, 25%, or 20%, or the like, which is not limited herein.

In some embodiments, the second dehumidification degree may characterize the ability of the second dehumidification apparatus 36 to adjust the humidity of the second space 34, for example, reducing the humidity of the second space 34 to 20%, 15%, 10%, 9%, 8%, 7%, 6%, 5%, 4%, 3%, 2%, 1%, or 0.1%, or the like, which is not limited herein.

In some application scenarios, the target humidity may be less than 20%. In some application scenarios, the target humidity may be less than 10%. In some application scenarios, the target humidity may be less than 5%. In some application scenarios, the target humidity may be less than 3%.

In some embodiments, the second dehumidification apparatus 36 may contain a solid moisture-absorbing material. The solid moisture-absorbing material may be configured to absorb water molecules in the air. In some embodiments, the solid moisture-absorbing material may include any one or more of activated carbon, activated alumina, silica gel, carbon molecular sieve, and zeolite molecular sieve.

After a period of research, the inventors of the present disclosure have found that if the surface temperature of a low-temperature object (such as the to-be-tested integrated chip 3 in the present embodiment) is lower than the dew point temperature of the air, and the saturation of water molecules in the air reaches 100%, dew condensation and/or frost formation may occur on the surface of the low-temperature object. The degree of dew condensation and/or frost formation on the surface of the to-be-tested integrated chip may depend on the surface temperature of the to-be-tested integrated chip, the ambient relative humidity, or the content of water molecules in the air.

In some application scenarios, the to-be-tested integrated chip 3 may need to be installed on the test socket 31 for low-temperature operation testing. If the air humidity is relatively high, as the temperature decreases, dew condensation and/or frost formation may occur on the surface of the to-be-tested integrated chip 3 or the test socket 31. Such dew condensation and/or frost formation on the surface of the to-be-tested integrated chip 3 or the test socket 31 may easily cause short circuits and damage to the to-be-tested integrated chip 3 or the test socket 31.

Common methods used by those skilled in the art to prevent frost formation on the to-be-tested integrated chip at low temperatures may include heating the surface of the to-be-tested integrated chip with a heating element, coating the surface of the to-be-tested integrated chip with an anti-frost coating, controlling the ambient humidity with a dehumidifier or air conditioner, or vibrating the to-be-tested integrated chip to prevent water vapor adhesion.

The inventors of the present disclosure have found that the above conventional technical solutions all have certain shortcomings. The method of heating the surface of the to-be-tested integrated chip with the heating element may make it difficult for the to-be-tested integrated chip to maintain a preset temperature, thereby failing to meet the testing requirements of the to-be-tested integrated chip. The method of coating the surface of the to-be-tested integrated chip may cause damage to the to-be-tested integrated chip, and it may be difficult to coat the surfaces of a large number of to-be-tested integrated chips in batches. Common dehumidifiers in the field can only control the ambient humidity above 10%, and if the target temperature is lower than −40 degrees Celsius, frost may still form on the surface of the to-be-tested integrated chip. Mechanical vibration of the to-be-tested integrated chip may not be applicable to to-be-tested integrated chips that are not resistant to vibration.

To address the shortcomings of the above solutions, the inventors of the present disclosure have used the first dehumidification apparatus and the second dehumidification apparatus to adjust the humidity of the first space and the second space respectively. Without the assistance of other auxiliary dehumidification methods, the humidity in the second space may be controlled within a very small range (for example, the humidity is controlled below 5%), so that no dew condensation and/or frost formation may occur on the surface of the target object at the target temperature.

Furthermore, the first air in the second space 34 may be sucked into the second dehumidification apparatus 36 through the first air intake channel 361, undergo the dehumidification by the second dehumidification apparatus 36 to obtain the second air. The second air may be injected into the second space 34 through the first air exhaust channel 362, thereby realizing dehumidification in the second space 34.

Due to the limited dehumidification capacity of solid dehumidification agent in the second dehumidification apparatus 36, it may no longer be able to dehumidify the first air after adsorbing more than a certain threshold of water molecules. That is, the second dehumidification apparatus 36 may not meet the dehumidification conditions at this time. Therefore, it may be necessary to perform a regeneration operation on the solid dehumidification agent in the second dehumidification apparatus 36.

In some application scenarios, the second dehumidification apparatus 36 may also selectively interact or communicate with the first space 33; More particularly, the second dehumidification apparatus 36 may selectively conduct air communication with the first space 33. In some embodiments, the air in the first space 33 may be heated and then introduced into the second dehumidification apparatus 36 through the second air intake channel 363, evaporating the water molecules in the second dehumidification apparatus 36, and re-enter the first space 33 through the second air exhaust channel 364. After the solid dehumidification agent in the second dehumidification apparatus 36 completes the regeneration operation, it may re-dehumidify the air in the second space 34.

When the second dehumidification apparatus 36 conducts air interaction with the first space 33, the second dehumidification apparatus 36 may not conduct air interaction with the second space.

After a period of research, the inventors of the present disclosure have found that if only the second dehumidification apparatus is used to dehumidify the first space and the second space, due to the limited dehumidification capacity of the second dehumidification apparatus per unit time, it may take a lot of time and energy to reduce the humidity in the second space to the target humidity. Considering the need to save energy and improve efficiency, the first dehumidification apparatus may be adopted to perform a first-level humidity adjustment on the first space and/or the second space, so that the humidity in the first space and/or the second space is lower than a certain range (for example, any one of 10%-15%, 15%-20%, 20%-25%, 20%-30%, 25%-30%). Then, the second dehumidification apparatus may be adopted to perform a second-level humidity adjustment on the second space, further adjusting the humidity to the target humidity (any one of below 10%, below 5%, below 3%, below 1%) on the basis of the above range, so that no dew condensation and/or frost formation may occur on the to-be-tested integrated chip in an environment below 0° C.

In some embodiments, a humidification apparatus (not illustrated in the drawings) may also be disposed in the second space 34 to increase the humidity of the second space 34 according to the chip testing requirements.

The above scheme, on the one hand, may use the thermoelectric cooling chip attached to one side of the to-be-tested integrated chip to independently realize the cooling or heating of the to-be-tested integrated chip. The above scheme may further use the heat exchange assembly attached to the first thermoelectric cooling chip to accelerate the speed at which the first thermoelectric cooling chip absorbs heat from the to-be-tested integrated chip or transfers heat to the to-be-tested integrated chip, so that the to-be-tested integrated chip may cool down or heat up quickly, and the testing efficiency of the to-be-tested integrated chip may be enhanced.

On the other hand, by arranging a second thermoelectric cooling chip in contact with the liquid cooling circuits in the heat exchange assembly: the second thermoelectric cooling chip may absorb heat from the coolant in the liquid cooling circuits, thereby further reducing the temperature of the second end face of the first thermoelectric cooling chip and enabling its first end face to reach a lower temperature; or, the second thermoelectric cooling chip may transfer heat to the coolant, thereby further increasing the temperature of the second end face of the first thermoelectric cooling chip and enabling its first end face to reach a higher temperature. In this way, the to-be-tested integrated chip may heat up or cool down faster, and the surface temperature of the to-be-tested integrated chip may easily reach below −40° C. or above 100° C.

Furthermore, by arranging the second dehumidification apparatus that interacts with the second space accommodating the to-be-tested integrated chip, the humidity of the second space may be reduced to below 10% before the low-temperature test of the to-be-tested integrated chip, thereby alleviating the dew condensation and frost formation problems of the to-be-tested integrated chip in an ambient temperature below 0° C.

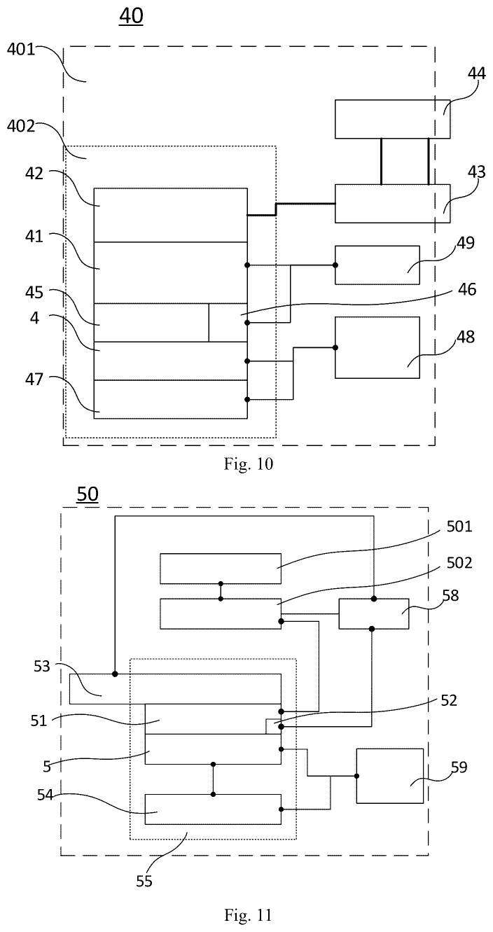

Please refer to FIG. 10. FIG. 10 is a schematic structural diagram of an integrated chip testing apparatus according to yet another embodiment of the present disclosure.

As illustrated in FIG. 10, an integrated chip testing apparatus 40 provided by the present disclosure may specifically include: a thermoelectric cooling chip 41, a metal heat exchanger 42, a primary liquid cooling module 43, a secondary liquid cooling module 44, a metal heat-conducting block 45, a temperature sensor 46, a chip test socket 47, a chip test board card 48, a temperature control board card 49, a first space 401, and a second space 402.

The thermoelectric cooling chip 41 may correspond to the first thermoelectric cooling chip 11 mentioned above. The metal heat exchanger 42 may correspond to the second heat-conducting member 15 mentioned above. The metal heat-conducting block 45 may correspond to the first heat-conducting member 121 mentioned above. Details are not described herein.

In some embodiments, coolant may circulate between the primary liquid cooling module 43 and the secondary liquid cooling module 44.

In the present embodiment, the primary liquid cooling module 43 may correspond to the radiator 14 mentioned above, and the secondary liquid cooling module 44 may correspond to the second thermoelectric cooling chip 131 mentioned above. Details are not described herein.

In some embodiments, the to-be-tested integrated chip 4, the thermoelectric cooling chip 41, the metal heat exchanger 42, the metal heat-conducting block 45, the temperature sensor 46, and the chip test socket 47 may be accommodated in the second space 402.

In some embodiments, the first space 401 may partially or fully accommodate the primary liquid cooling module 43 and/or the secondary liquid cooling module 44. In the present embodiment, the first space 401 may be configured to partially accommodate the primary liquid cooling module 43 and the secondary liquid cooling module 44.

Further, the first space 401 may also be configured to accommodate the chip test board card 48 and the temperature control board card 49.

The temperature control board card 49 may be communicatively connected to each of the temperature sensor 46 and the thermoelectric cooling chip 41. In some embodiments, the communication connection may include a wired connection or a wireless connection. In the present embodiment, the temperature control board card 49 may be wiredly connected to each of the temperature sensor 46 and the thermoelectric cooling chip 41. The temperature control board card 49 may be configured to obtain the current temperature measured by the temperature sensor 46, determine the difference between the current temperature and the target temperature of the to-be-tested integrated chip 4 in the test requirements, and decide whether to increase the cooling capacity or heating capacity of the thermoelectric cooling chip 41.

The chip test board card 48 may be coupled to the chip test socket 47. The chip test board card 48 may be configured to perform tests on the to-be-tested integrated chip 4 coupled to the chip test socket 47.

In some embodiments, each of the chip test board card 48 and the temperature control board card 49 may also be coupled to an upper computer (not illustrated in the drawings) disposed outside the first space 401 through a control bus. In some embodiments, the upper computer may be configured to issue test instructions to the chip test board card 48 and the temperature control board card 49.

For the above scheme, on the one hand, the thermoelectric cooling chip attached to one side of the to-be-tested integrated chip may be configured to independently realize the cooling or heating of the to-be-tested integrated chip. Further, the heat exchange assembly attached to the first thermoelectric cooling chip may be configured to accelerate the speed at which the first thermoelectric cooling chip absorbs heat from the to-be-tested integrated chip or transfers heat to the to-be-tested integrated chip, so that the to-be-tested integrated chip may cool down or heat up quickly, and the testing efficiency of the to-be-tested integrated chip may be enhanced.

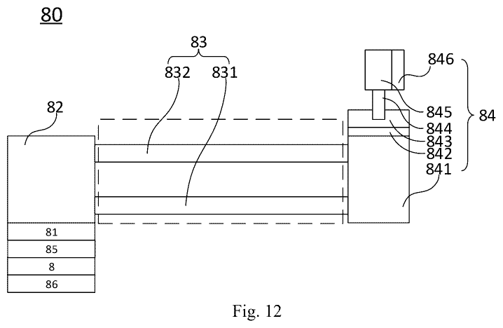

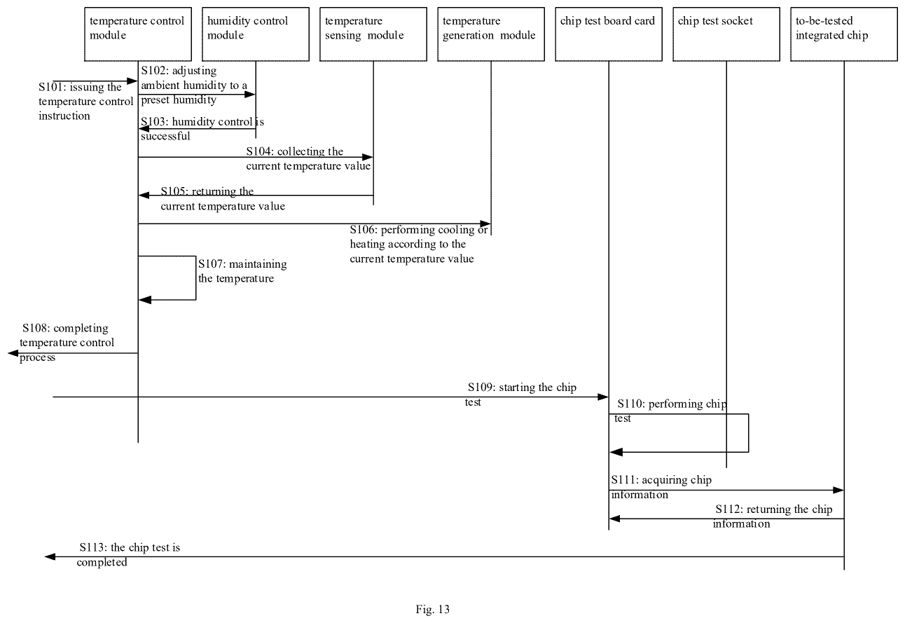

Please refer to FIG. 11. FIG. 11 is a schematic structural diagram of an integrated chip testing apparatus according to yet another embodiment of the present disclosure.

As illustrated in FIG. 11, an integrated chip testing apparatus 50 may specifically include: a thermoelectric cooling chip 51, a temperature sensor 52, a multi-stage hybrid low-temperature liquid cooling module 53, a chip test socket 54, a second space 55, a first space 56, a chip test board 57, an MCU 58, a power supply 501, and a voltage conversion module 502.

In the present embodiment, the chip test board 57 may be electrically connected to each of the chip test socket 54 and the to-be-tested integrated chip 5.

The thermoelectric cooling chip 51 may correspond to the first thermoelectric cooling chip 11 mentioned above, and details are not repeated herein.

In some embodiments, a first face of the thermoelectric cooling chip 51 may be in contact with a partial face of the to-be-tested integrated chip 5, a first face of the temperature sensor 52 may be in contact with the first face of the thermoelectric cooling chip 51, and a second face of the temperature sensor 52 may be in contact with a partial face of the to-be-tested integrated chip 5. The temperature sensor may be configured to obtain the current temperature of the to-be-tested integrated chip 5, and adjust, according to the difference between the current temperature and the set temperature, the cooling power or heating power of the thermoelectric cooling chip 51. In some embodiments, the number of temperature sensors 52 may be one or more, so as to more accurately obtain the current temperature of the to-be-tested integrated chip 5.

The multi-stage hybrid low-temperature liquid cooling module 53 may correspond to the temperature adjustment apparatus 10 mentioned above, and the chip test socket 54 may correspond to the test socket 21 mentioned above, and details are not repeated herein.

The power supply 501 may be electrically connected to the voltage conversion module 502, and the voltage conversion module 502 may be further electrically connected to the thermoelectric cooling chip 51. The voltage conversion module 502 may be configured to provide the converted voltage to the thermoelectric cooling chip 51.

In some embodiments, the power supply 501 may provide 380V or 240V alternating current. In some embodiments, the power supply 501 may provide 5V, 12V, 24V, 36V, 48V, 60V, 110V, or 220V direct current.

In some embodiments, an input voltage of the thermoelectric cooling chip 51 may be direct current lower than 100V. For example, the input voltage of the thermoelectric cooling chip may be 5V, 12V, 24V, 36V, or 48V. In some application scenarios, the voltage conversion module 502 may, on the one hand, be configured to convert the alternating current input from the power supply into direct current; on the other hand, be configured to step down the direct current higher than 100V to a direct current suitable for the thermoelectric cooling chip 51; and, on the third hand, be configured to adjust the voltage value applied to the thermoelectric cooling chip 51, thereby adjusting the cooling/heating power of the thermoelectric cooling chip 51.

In some embodiments, the MCU 58 may be communicatively connected to each of the temperature sensor 52, the multi-stage hybrid low-temperature liquid cooling module 53, the chip test board 57, and the voltage conversion module 502. In some embodiments, the MCU 58 may perform functions including current temperature collection, adjusting the voltage value applied to the thermoelectric cooling chip 51 to realize temperature adjustment of the thermoelectric cooling chip 51, controlling the liquid cooling module, and acquiring the current operating status of the test board. In some application scenarios, the MCU 58 may also be communicatively connected to a second dehumidification apparatus (not illustrated in the drawings) that communicates with the second space 55, so as to control the humidity in the second space 55, and when the internal temperature of the second space 55 is lower than 0° C., avoid dew condensation and/or frost formation on the accommodated to-be-tested integrated chip 5 and/or the chip test socket 54 due to excessively high humidity in the second space 55.

In some application scenarios, the MCU controller 59 may perform part or all of the functions of the temperature control board card 49 mentioned above.

For the above scheme, on the one hand, the thermoelectric cooling chip attached to one side of the to-be-tested integrated chip may be configured to independently realize the cooling or heating of the to-be-tested integrated chip. Further, the heat exchange assembly attached to the first thermoelectric cooling chip may be configured to accelerate the speed at which the first thermoelectric cooling chip absorbs heat from the to-be-tested integrated chip or transfers heat to the to-be-tested integrated chip, so that the to-be-tested integrated chip may cool down or heat up quickly, and the testing efficiency of the to-be-tested integrated chip may be enhanced.

On the other hand, by arranging a second thermoelectric cooling chip in contact with the liquid cooling circuits in the heat exchange assembly: the second thermoelectric cooling chip may absorb heat from the coolant in the liquid cooling circuits, thereby further reducing the temperature of the second end face of the first thermoelectric cooling chip and enabling its first end face to reach a lower temperature; or, the second thermoelectric cooling chip may transfer heat to the coolant, thereby further increasing the temperature of the second end face of the first thermoelectric cooling chip and enabling its first end face to reach a higher temperature. In this way, the to-be-tested integrated chip may heat up or cool down faster, and the surface temperature of the to-be-tested integrated chip may easily reach below −40° C. or above 100° C.

Furthermore, by arranging the second dehumidification apparatus that interacts with the second space accommodating the to-be-tested integrated chip, the humidity of the second space may be reduced to below 10% before the low-temperature test of the to-be-tested integrated chip, thereby alleviating the dew condensation and frost formation problems of the to-be-tested integrated chip in an ambient temperature below 0° C.

Please refer to FIG. 12. FIG. 12 is a schematic structural diagram of an integrated chip testing apparatus according to yet another embodiment of the present disclosure.

As illustrated in FIG. 12, the integrated chip testing apparatus 80 may specifically include a first thermoelectric cooling chip 81, a metal heat exchanger 82, a coolant channel 83, a liquid cooling module 84, a metal heat-conducting block 85, and a chip test socket 86.

A to-be-tested chip 8 may correspond to the to-be-tested chip 4 mentioned above. The first thermoelectric cooling chip 81 may correspond to the first semiconductor 11 mentioned above. The metal heat exchanger 82 may correspond to the first heat-conducting member 15 mentioned above. The metal heat-conducting block 85 may correspond to the chip test socket 47 mentioned above. The chip test socket 86 may correspond to the chip test socket 47 mentioned above. Details are not repeated herein.

In some embodiments, the coolant channel 83 may further include a coolant inlet channel 831 and a coolant outlet channel 832. The coolant inlet channel 831 may be configured to circulate the coolant from the liquid cooling circuit (not illustrated in the drawings) inside the metal heat exchanger 82 to the liquid cooling module 84, and the coolant outlet channel 832 may be configured to circulate the coolant from the liquid cooling module 84 to the liquid cooling circuit of the metal heat exchanger 82.

In some embodiments, the coolant inlet channel 831 and/or the coolant outlet channel 832 may also be provided with a liquid pump (not illustrated in the drawings).

In some embodiments, an outer surface of the pipe of the coolant inlet channel 831 may be partially or fully provided with heat dissipation fins (not illustrated in the drawings). In some application scenarios, in a case where the metal heat exchanger 82 is configured to absorb heat from the first thermoelectric cooling chip 81 (i.e., the coolant in the coolant inlet channel 831 has absorbed heat), to reduce the temperature of the coolant entering the liquid cooling module 84, the heat dissipation fins may be configured to absorb part of the heat of the coolant. Further, a cooling fan (not illustrated in the drawings) may also be configured to blow air to the heat dissipation fins, so as to accelerate the cooling rate of the coolant in the coolant inlet channel 831.

Further, the liquid cooling module 84 may be configured to absorb heat from the coolant in the coolant inlet channel 831 or release heat to the coolant in the coolant inlet channel 831.

In some embodiments, the liquid cooling module 84 may specifically include a heat exchanger 841, a second thermoelectric cooling chip 842, a metal base 843, a heat pipe 844, a heat dissipation fin 845, and a cooling fan 846.

In some embodiments, a liquid cooling circuit (not illustrated in the drawings) may also be provided inside the heat exchanger 841, and the second thermoelectric cooling chip 842 may be configured to absorb heat from the coolant in the liquid cooling circuit or release heat to the coolant in the liquid cooling circuit.

In some embodiments, one end face of the second thermoelectric cooling chip 842 may be attached to the heat exchanger 841, and another end face of the second thermoelectric cooling chip 842 may be attached to the metal base 843.

In some application scenarios, the metal base 843 may also be provided with an electric heating wire (not illustrated in the drawings). In a case where the second thermoelectric cooling chip 842 is used to release heat to the coolant in the liquid cooling circuit, the electric heating wire may be configured to provide heat to the second thermoelectric cooling chip 842.

In some embodiments, the heat pipe 844 may be partially inserted into the metal base 843 to increase a contact area between the heat pipe 844 and the metal base 843, thereby further enhancing the heat dissipation capacity of the liquid cooling module 84. In some embodiments, the heat pipe 844 may be attached to an outer surface of the metal base 843.

In some embodiments, the heat pipe 844 may pass through and be fitted with the heat dissipation fins 845. In a case where the second thermoelectric cooling chip 842 is used to absorb heat from the coolant in the liquid cooling circuit inside the heat exchanger 841, the metal base 843, the heat pipe 844, and the heat dissipation fins 845 may cooperate with each other to dissipate the heat absorbed by the second thermoelectric cooling chip 842 into the environment.

Further, the cooling fan 846 may also be attached to the heat dissipation fin 845. In a case where the second thermoelectric cooling chip 842 is used to absorb heat from the coolant in the liquid cooling circuit inside the heat exchanger 841, the cooling fan 846 may increase the rate at which the heat absorbed by the second thermoelectric cooling chip 842 is dissipated into the environment. In some application scenarios, in a case where the second thermoelectric cooling chip 842 is used to release heat to the coolant in the liquid cooling circuit inside the heat exchanger 841, the cooling fan 846 may not operate.

The number of the metal base 843, the heat pipe 844, the heat dissipation fin 845, and the cooling fan 846 may be multiple. In a case where the second thermoelectric cooling chip 842 is used to absorb heat from the coolant in the liquid cooling circuit inside the heat exchanger 841, the rate at which the heat absorbed by the second thermoelectric cooling chip is dissipated into the environment may be further increased.

For the above scheme, on the one hand, the thermoelectric cooling chip attached to one side of the to-be-tested integrated chip may be configured to independently realize the cooling or heating of the to-be-tested integrated chip. Further, the heat exchange assembly attached to the first thermoelectric cooling chip may be configured to accelerate the speed at which the first thermoelectric cooling chip absorbs heat from the to-be-tested integrated chip or transfers heat to the to-be-tested integrated chip, so that the to-be-tested integrated chip may cool down or heat up quickly, and the testing efficiency of the to-be-tested integrated chip may be enhanced.

On the other hand, by arranging a second thermoelectric cooling chip in contact with the liquid cooling circuits in the heat exchange assembly: the second thermoelectric cooling chip may absorb heat from the coolant in the liquid cooling circuits, thereby further reducing the temperature of the second end face of the first thermoelectric cooling chip and enabling its first end face to reach a lower temperature; or, the second thermoelectric cooling chip may transfer heat to the coolant, thereby further increasing the temperature of the second end face of the first thermoelectric cooling chip and enabling its first end face to reach a higher temperature. In this way, the to-be-tested integrated chip may heat up or cool down faster, and the surface temperature of the to-be-tested integrated chip may easily reach below −40° C. or above 100° C.

Please refer to FIG. 13. FIG. 13 is a schematic flowchart of an integrated chip testing method according to an embodiment of the present disclosure.

The integrated chip testing method provided by the present disclosure may be specifically executed by an integrated chip testing module. In some application scenarios, the integrated chip testing module may be the integrated chip testing apparatus itself mentioned above. In some application scenarios, the integrated chip testing module may be an embedded device communicatively connected to the aforementioned integrated chip testing apparatus via wired or wireless communication, or may be a user equipment (UE), a mobile device, a user terminal, a terminal, a cellular phone, a cordless phone, a personal digital assistant (PDA), a handheld device, a computing device, a vehicle-mounted device, a wearable device, or products such as glasses or helmets for augmented reality or virtual reality, which is not limited herein.

In some application scenarios, the integrated chip testing module may be the MCU 58 in the aforementioned integrated chip testing apparatus.

As illustrated in FIG. 13, the integrated chip testing method according to an embodiment of the present disclosure may specifically include the operations illustrated at blocks of FIG. 13.

The operation at block S101: issuing a temperature control instruction.

In some embodiments, the user may issue a temperature setting instruction to a temperature control module through the integrated chip testing module.

The temperature control module may correspond to the temperature adjustment apparatus 10 mentioned above, and details are not repeated herein.

In some embodiments, the temperature setting instruction may include the preset temperature value.

The operation at block S102: adjusting ambient humidity to a preset humidity.

Before adjusting the temperature of the to-be-tested integrated chip, the integrated chip testing module may first use a humidity control module to adjust the ambient humidity in the second space.

The adjustment of ambient humidity may include reducing humidity or increasing humidity.

In some embodiments, when the to-be-tested integrated chip needs to be tested at a temperature below 0° C., if the ambient humidity is not controlled below 20%, the temperature of the cold face of the first thermoelectric cooling chip and/or the surface of the to-be-tested integrated chip may be lower than the temperature in the second space, and dew condensation and/or frost formation may occur on the surface of the to-be-tested integrated chip. Such phenomena may cause short circuits and damage to the to-be-tested integrated chip. To avoid the occurrence of the above phenomena, the first dehumidification apparatus arranged in the first space and the second dehumidification apparatus arranged in the second space may be configured to further reduce the humidity in the second space to below 10%, thereby preventing dew condensation or frost formation on the surface of the to-be-tested integrated chip when the surface temperature of the to-be-tested integrated chip is below 0° C.

In some embodiments, when the to-be-tested integrated chip needs to undergo a high-temperature and high-humidity test, the humidification apparatus in the second space may be configured to increase the ambient humidity.

The operation at block S103: humidity control is successful.

In some embodiments, a humidity sensor may also be arranged in the second space. When the humidity sensor obtains that the current humidity is equal to the preset humidity and this state maintains for a certain period of time, the humidity control module may feedback a humidity control success signal to the integrated chip testing module.

The operation at block S104: collecting the current temperature value.

In some embodiments, since the cooling and heating power of the first thermoelectric cooling chip in the temperature adjustment apparatus provided by the present disclosure exceeds 100 W, i.e., the temperature adjustment rate of the first thermoelectric cooling chip is very high, in order to improve the accuracy of temperature adjustment, the integrated chip testing module may first use the temperature sensor to collect the current temperature value of the to-be-tested integrated chip before performing temperature adjustment. The temperature sensor is in contact with each of the first thermoelectric cooling chip and the to-be-tested integrated chip.

The operation at block S105: returning the current temperature value.

In some embodiments, the temperature sensor may return the collected current temperature value to the integrated chip testing module.

In some embodiments, the number of temperature sensors may be more than one. The integrated chip testing module may perform numerical processing, such as averaging or taking the median, of the temperature values collected by the multiple current temperature sensors, so as to obtain the current temperature value.

The operation at block S106: performing cooling or heating according to the current temperature value.

In some embodiments, the integrated chip testing module may use the temperature generation module, according to the difference between the current temperature value and the preset temperature value, to perform cooling or heating.

The temperature generation module may correspond to the MCU mentioned above, and details are not repeated herein.

The operation at block S107: maintaining the temperature.

In some embodiments, in the process of executing the operations at blocks S106-S107, to enhance the efficiency and accuracy of temperature adjustment, the integrated chip testing module may apply one or a combination of multiple algorithms including proportional-integral-derivative (PID) control, fuzzy control, neural network control, adaptive control, sliding mode control, linear quadratic regulator (LQR) control, or reinforcement learning-based control algorithms, which is not limited herein.

The operation at block S108: completing temperature control process.

When the temperature sensor collects that the temperature value on the surface of the to-be-tested chip maintains the preset temperature value for a period of time, for example, 5 min, 10 min, or 15 min, the temperature control process may be completed.

The operation at block S109: starting the chip test.

In some embodiments, the integrated chip testing module may issue a chip test instruction to the chip test board card.

The chip test board card may correspond to the chip test board card 48 mentioned above, and details are not repeated herein.

The operation at block S110: performing chip test.

In some embodiments, the chip test board card may test the to-be-tested integrated chip.

The operation at block S111: acquiring chip information.

In some embodiments, during the test of the to-be-tested integrated chip, the chip test board card may acquire operating information of the to-be-tested chip.

The operation at block S112: returning the chip information.

The operation at block S113: the chip test is completed.

For the above scheme, on the one hand, the thermoelectric cooling chip attached to one side of the to-be-tested integrated chip may be configured to independently realize the cooling or heating of the to-be-tested integrated chip. Further, the heat exchange assembly attached to the first thermoelectric cooling chip may be configured to accelerate the speed at which the first thermoelectric cooling chip absorbs heat from the to-be-tested integrated chip or transfers heat to the to-be-tested integrated chip, so that the to-be-tested integrated chip may cool down or heat up quickly, and the testing efficiency of the to-be-tested integrated chip may be enhanced.

On the other hand, by arranging a second thermoelectric cooling chip in contact with the liquid cooling circuits in the heat exchange assembly: the second thermoelectric cooling chip may absorb heat from the coolant in the liquid cooling circuits, thereby further reducing the temperature of the second end face of the first thermoelectric cooling chip and enabling its first end face to reach a lower temperature; or, the second thermoelectric cooling chip may transfer heat to the coolant, thereby further increasing the temperature of the second end face of the first thermoelectric cooling chip and enabling its first end face to reach a higher temperature. In this way, the to-be-tested integrated chip may heat up or cool down faster, and the surface temperature of the to-be-tested integrated chip may easily reach below −40° C. or above 100° C.

Furthermore, by arranging the second dehumidification apparatus that interacts with the second space accommodating the to-be-tested integrated chip, the humidity of the second space may be reduced to below 10% before the low-temperature test of the to-be-tested integrated chip, thereby alleviating the dew condensation and frost formation problems of the to-be-tested integrated chip in an ambient temperature below 0° C.

The above descriptions are only embodiments of the present disclosure, and are not intended to limit the patent scope of the present disclosure. Any equivalent structure or equivalent process transformation made by using the contents of the specification and drawings of the present disclosure, or directly or indirectly applied in other related technical fields, shall similarly be included in the patent protection scope of the present disclosure.

1. A temperature adjustment apparatus, applied to an integrated chip testing scenario and comprising:
a first thermoelectric cooling chip, a first end face of the first thermoelectric cooling chip is configured to attach to one side of a to-be-tested integrated chip, and is configured to absorb heat from the to-be-tested integrated chip or transfer heat to the to-be-tested integrated chip; and
a heat exchange assembly, attached to a second end face of the first thermoelectric cooling chip, and configured to perform heat exchange with the first thermoelectric cooling chip.

2. The temperature adjustment apparatus as claimed in claim 1, wherein the heat exchange assembly comprises:
a first heat-conducting member, attached to the second end face of the first thermoelectric cooling chip; and
a liquid cooling assembly, a part of liquid cooling circuits of the liquid cooling assembly is disposed in the first heat-conducting member, the liquid cooling assembly is configured to perform heat exchange with the first heat-conducting member by circulating the coolant in the liquid cooling circuits according to a testing requirement of the integrated chip.

3. The temperature adjustment apparatus as claimed in claim 2, wherein
the liquid cooling assembly comprises a second thermoelectric cooling chip, the second thermoelectric cooling chip is in contact with another part of liquid cooling circuits of the liquid cooling assembly, and the second thermoelectric cooling chip is configured to perform heat exchange with the liquid cooling circuits.

4. The temperature adjustment apparatus as claimed in claim 2, wherein
the liquid cooling assembly further comprises a radiator, and the radiator is configured to further dissipate the heat absorbed by the coolant when the coolant absorbs heat from the first heat-conducting member.

5. The temperature adjustment apparatus as claimed in claim 1, further comprises:
a second heat-conducting member, a first end face of the second heat-conducting member is configured to attach to one side of the to-be-tested integrated chip, and is configured to perform heat exchange with the to-be-tested integrated chip, and a second end face of the second heat-conducting member is attached to the first end face of the first thermoelectric cooling chip.

6. The temperature adjustment apparatus as claimed in claim 5, wherein
a heat-conducting material is coated between the second end face of the second heat-conducting member and the first end face of the first thermoelectric cooling chip; and/or the heat-conducting material is coated between the first end face of the second heat-conducting member and one side of the to-be-tested integrated chip.

7. The temperature adjustment apparatus as claimed in claim 1, wherein
the first thermoelectric cooling chip is a single-stage Peltier element,
in a case of dissipating the heat absorbed from the to-be-tested integrated chip, the first end face of the first thermoelectric cooling chip is a cold face, and the second end face of the first thermoelectric cooling chip is a hot face; and
in a case of transferring heat to the to-be-tested integrated chip through the first thermoelectric cooling chip, the first end face of the first thermoelectric cooling chip is a hot face, and the second end face of the first thermoelectric cooling chip is a cold face.

8. The temperature adjustment apparatus as claimed in claim 1, further comprising:
a temperature adjustment unit, configured to perform voltage inversion on the first end face and the second end face of the first thermoelectric cooling chip to realize switching between a cold face and a hot face.

9. The temperature adjustment apparatus as claimed in claim 3, further comprising:
a temperature adjustment unit, configured to perform voltage inversion on two end faces of the second thermoelectric cooling chip, to realize switching between a cold face and a hot face.

10. A testing apparatus for an integrated chip, wherein the testing apparatus comprises:
a test socket, configured to place the to-be-tested integrated chip;
a test board, coupled to the test socket to realize testing of the to-be-tested integrated chip; and
a temperature adjustment apparatus, configured to perform temperature adjustment in a case of testing the to-be-tested integrated chip, wherein the temperature adjustment apparatus comprises:
a first thermoelectric cooling chip, a first end face of the first thermoelectric cooling chip is configured to attach to one side of a to-be-tested integrated chip, and is configured to absorb heat from the to-be-tested integrated chip or transfer heat to the to-be-tested integrated chip; and
a heat exchange assembly, attached to a second end face of the first thermoelectric cooling chip, and configured to perform heat exchange with the first thermoelectric cooling chip.

11. The temperature adjustment apparatus as claimed in claim 10, wherein
the heat exchange assembly comprises:
a first heat-conducting member, attached to the second end face of the first thermoelectric cooling chip; and
a liquid cooling assembly, a part of liquid cooling circuits of the liquid cooling assembly is disposed in the first heat-conducting member, the liquid cooling assembly is configured to perform heat exchange with the first heat-conducting member by circulating the coolant in the liquid cooling circuits according to a testing requirement of the integrated chip.

12. The temperature adjustment apparatus as claimed in claim 11, wherein
the liquid cooling assembly comprises a second thermoelectric cooling chip, the second thermoelectric cooling chip is in contact with another part of liquid cooling circuits of the liquid cooling assembly, and the second thermoelectric cooling chip is configured to perform heat exchange with the liquid cooling circuits.

13. The temperature adjustment apparatus as claimed in claim 11, wherein
the liquid cooling assembly further comprises a radiator, and the radiator is configured to further dissipate the heat absorbed by the coolant when the coolant absorbs heat from the first heat-conducting member.

14. The temperature adjustment apparatus as claimed in claim 10, further comprises:
a second heat-conducting member, a first end face of the second heat-conducting member is configured to attach to one side of the to-be-tested integrated chip, and is configured to perform heat exchange with the to-be-tested integrated chip, and a second end face of the second heat-conducting member is attached to the first end face of the first thermoelectric cooling chip.

15. The temperature adjustment apparatus as claimed in claim 14, wherein
a heat-conducting material is coated between the second end face of the second heat-conducting member and the first end face of the first thermoelectric cooling chip; and/or
the heat-conducting material is coated between the first end face of the second heat-conducting member and one side of the to-be-tested integrated chip.

16. The temperature adjustment apparatus as claimed in claim 10, wherein
the first thermoelectric cooling chip is a single-stage Peltier element,
in a case of dissipating the heat absorbed from the to-be-tested integrated chip, the first end face of the first thermoelectric cooling chip is a cold face, and the second end face of the first thermoelectric cooling chip is a hot face; and
in a case of transferring heat to the to-be-tested integrated chip through the first thermoelectric cooling chip, the first end face of the first thermoelectric cooling chip is a hot face, and the second end face of the first thermoelectric cooling chip is a cold face.

17. The temperature adjustment apparatus as claimed in claim 10, further comprising:
a temperature adjustment unit, configured to perform voltage inversion on the first end face and the second end face of the first thermoelectric cooling chip to realize switching between a cold face and a hot face.

18. The temperature adjustment apparatus as claimed in claim 12, further comprising:
a temperature adjustment unit, configured to perform voltage inversion on two end faces of the second thermoelectric cooling chip, to realize switching between a cold face and a hot face.

19. The testing apparatus as claimed in claim 18, further defining:
a first space; and
a second space, accommodated in the first space; and, configured to accommodate the to-be-tested integrated chip, the test socket and the first thermoelectric cooling chip, so that the to-be-tested integrated chip meets a testing requirement at a target temperature.

20. The testing apparatus as claimed in claim 19, further comprising:
a first dehumidification apparatus, disposed in the first space and configured to reduce humidity in the first space according to a first dehumidification degree.
